(19) United States
(12) Patent Application Publication
(10) Pub. No.: US 2026/0215175 A1
(43) Pub. Date: Jul. 23, 2026

(54) FILM-FORMING METHOD AND FILM-FORMING APPARATUS

(71) Applicant: Tokyo Electron Limited, Tokyo (JP)

(72) Inventors: Rui KANEMURA, Yamanashi (JP); Dong LIANG, Shanghai (CN); Tatsuya MIYAHARA, Yamanashi (JP); Yoshihiro TAKEZAWA, Yamanashi (JP)

(21) Appl. No.: 19/441,127

(22) Filed: Jan. 6, 2026

(30) Foreign Application Priority Data
Jan. 14, 2025 (JP) 2025-004515

(51) Int. Cl. H10P 14/24; C23C 16/52; H10P 14/20

(52) U.S. Cl. CPC H10P 14/24; C23C 16/52; H10P 14/3411

(57) ABSTRACT

A film-forming method includes: preparing a substrate in which an insulating film is formed at a surface of the substrate; generating crystal nuclei containing silicon on the insulating film; and growing the generated crystal nuclei.

### CROSS-REFERENCE TO RELATED APPLICATIONS

This application is based upon and claims priority to Japanese Patent Application No. 2025-004515, filed on Jan. 14, 2025, the entire contents of which are incorporated herein by reference.

### BACKGROUND OF THE INVENTION

### 1. Field of the Invention

The present disclosure relates to a film-forming method and a film-forming apparatus.

### 2. Description of the Related Art

Japanese Patent Application Publication No. 2020-167307 discloses that a film having good surface roughness and step coverage is formed by simultaneously supplying a first raw material gas containing silicon or germanium and hydrogen and a second raw material gas containing silicon or germanium and a halogen element.

### SUMMARY OF THE INVENTION

A film-forming method according to one aspect of the present disclosure includes preparing a substrate in which an insulating film is formed at a surface of the substrate; generating crystal nuclei containing silicon on the insulating film; and growing the generated crystal nuclei.

### BRIEF DESCRIPTION OF THE DRAWINGS

FIG. 1 is a flowchart illustrating a film-forming method according to an embodiment;

FIG. 2 is a cross-sectional diagram (1) illustrating the film-forming method according to an embodiment;

FIG. 3 is a cross-sectional diagram (2) illustrating the film-forming method according to an embodiment;

FIG. 4 is a cross-sectional diagram (3) illustrating the film-forming method according to an embodiment;

FIG. 5 is a cross-sectional diagram (4) illustrating the film-forming method according to an embodiment;

FIG. 6 is a cross-sectional diagram (5) illustrating the film-forming method according to an embodiment;

FIG. 7 is a vertical cross-sectional diagram illustrating a film-forming apparatus according to an embodiment;

FIG. 8 is a horizontal cross-sectional diagram illustrating the film-forming apparatus according to an embodiment;

FIG. 9 is a table presenting conditions for generating crystal nuclei of silicon germanium;

FIG. 10 is a diagram (1) illustrating the results of observing crystal nuclei of silicon germanium;

FIG. 11 is a diagram (2) illustrating the results of observing crystal nuclei of silicon germanium; and

FIG. 12 is a diagram (3) illustrating the results of observing crystal nuclei of silicon germanium.

### DESCRIPTION OF THE PREFERRED EMBODIMENTS

Hereinafter, non-limiting exemplary embodiments of the present disclosure will be described with reference to the accompanying drawings. In all the accompanying drawings, the same or corresponding reference numerals are used to designate the same or corresponding members or components, and duplicate descriptions may be omitted.

### Film-Forming Method

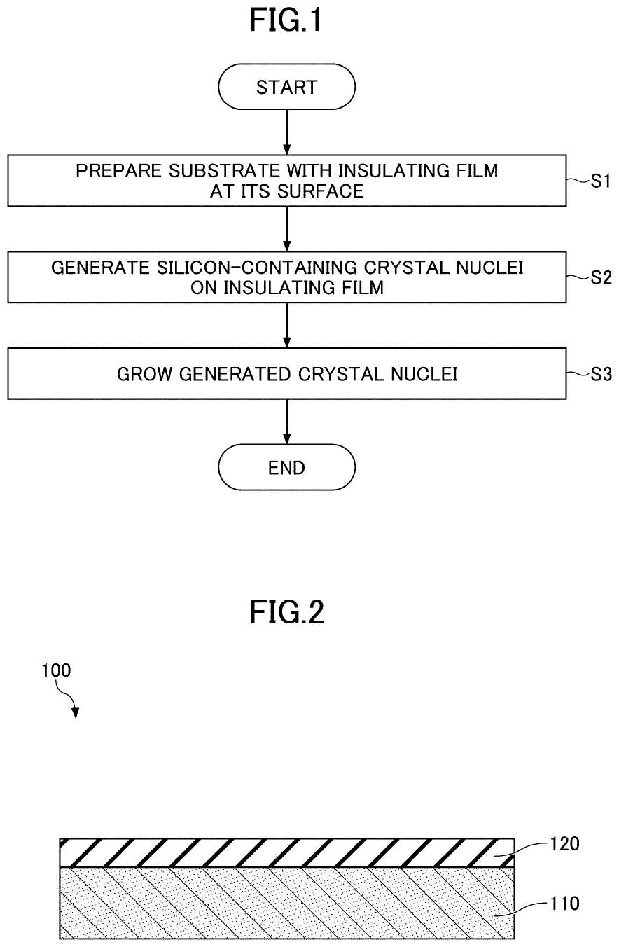

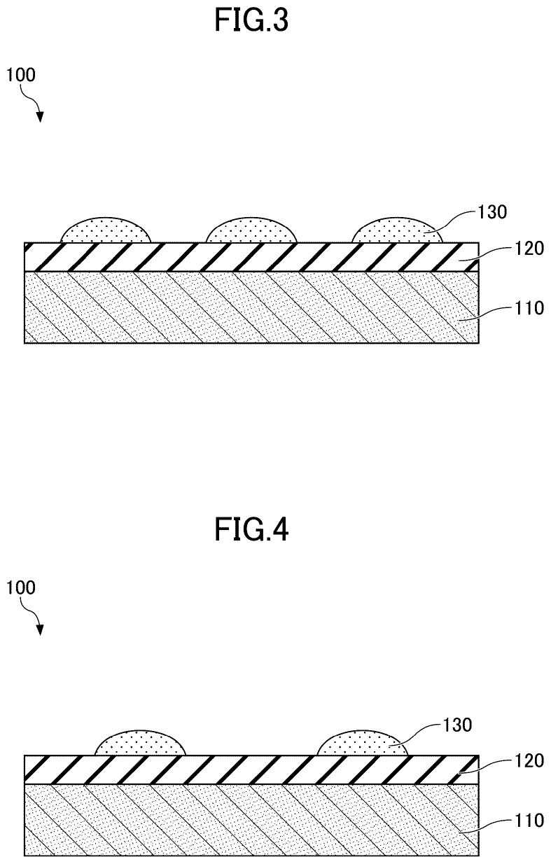

A film-forming method according to an embodiment will be described with reference to FIGS. 1 to 6. FIG. 1 is a flowchart illustrating a film-forming method according to an embodiment. FIGS. 2 to 6 are cross-sectional diagrams illustrating the film-forming method according to an embodiment. The film-forming method according to an embodiment includes steps S1 to S3 as depicted in FIG. 1.

In step S1, as illustrated in FIG. 2, a substrate 100 is prepared. The substrate 100 includes a base substrate 110 and an insulating film 120. The base substrate 110 is, for example, a silicon substrate. The insulating film 120 is provided at a surface of the substrate 100. The insulating film 120 is provided on the base substrate 110. The insulating film 120 is, for example, a silicon oxide film. The insulating film 120 may be a silicon nitride film.

In step S2, as illustrated in FIG. 3, crystal nuclei 130 containing silicon (Si) are generated on the insulating film 120. The crystal nuclei 130 are, for example, crystal nuclei of silicon germanium (SiGe). The crystal nuclei of silicon germanium can be generated, for example, by supplying a mixed gas of monosilane (SiH₄) gas, monogermane (GeH₄) gas, and hydrogen (H₂) gas to the substrate 100. The temperature of the substrate 100 when the crystal nuclei of silicon germanium are generated is, for example, 250° C. or more and 600° C. or less. Monosilane gas is an example of a silicon-containing gas. Monogermane gas is an example of a germanium-containing gas.

In step S2, the density of the crystal nuclei 130 may be controlled by changing one or more of the flow rate ratio of monogermane gas to monosilane gas, the temperature of the substrate 100, or the pressure of the space in which the substrate 100 is present. For example, by increasing the flow rate ratio of monogermane gas to monosilane gas, the density of the crystal nuclei 130 can be reduced as illustrated in FIG. 4. For example, by lowering the temperature of the substrate 100, the density of the crystal nuclei 130 can be reduced as illustrated in FIG. 4. For example, by lowering the pressure of the space in which the substrate 100 is present, the density of the crystal nuclei 130 can be reduced as illustrated in FIG. 4.

In step S2, the crystal nuclei 130 may be the crystal nuclei of silicon. The crystal nuclei of silicon can be generated, for example, by supplying a mixed gas of monosilane gas and hydrogen gas without supplying monogermane gas to the substrate 100. The temperature of the substrate 100 at the time of generating the crystal nuclei of silicon is, for example, 300° C. or more and 700° C. or less.

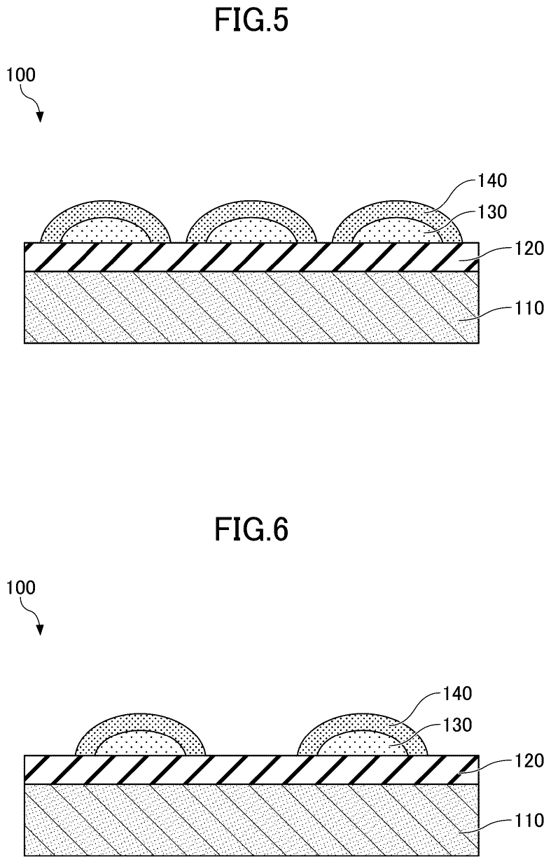

In step S3, as illustrated in FIGS. 5 and 6, the crystal nuclei 130 generated in step S2 are grown. For example, by supplying a mixed gas of monosilane gas, monogermane gas, and hydrogen gas to the substrate 100 at a flow rate ratio of monogermane gas to monosilane gas higher than that in step S2, the crystal nuclei 130 can be grown. While monogermane gas is easily adsorbed on the surface of silicon and the surface of silicon germanium, it is not easily adsorbed on the surface of the insulating film 120. Therefore, when the mixed gas of monosilane gas, monogermane gas, and hydrogen gas is supplied to the substrate 100 at the flow rate ratio of monogermane gas to monosilane gas higher than that in step S2, monogermane gas is adsorbed on the surface of the crystal nuclei 130. In contrast, monogermane gas is not or hardly adsorbed on the surface of the insulating film 120. As a result, the crystal nuclei 130 generated in step S2 can be grown without generating crystal nuclei 130 on the surface of the insulating film 120. That is, the crystal nuclei 140 are grown so as to cover the crystal nuclei 130. Therefore, when the crystal nuclei 130 illustrated in FIG. 3 are grown, the crystal nuclei 140 are grown while maintaining the density of the crystal nuclei 130 as illustrated in FIG. 5. When the crystal nuclei 130 illustrated in FIG. 4 are grown, the crystal nuclei 140 are grown while maintaining the density of the crystal nuclei 130 as illustrated in FIG. 6. The germanium atom concentration of the crystal nuclei 140 is higher than that of the crystal nuclei 130. The temperature of the substrate 100 when the crystal nuclei 130 are grown by using the mixed gas of monosilane gas, monogermane gas, and hydrogen gas is, for example, 250° C. or more and 600° C. or less.

In step S3, the size of the crystal nuclei 130 can be controlled by changing the time for supplying the mixed gas of monosilane gas, monogermane gas, and hydrogen gas to the substrate 100.

In step S3, instead of supplying the mixed gas of monosilane gas, monogermane gas, and hydrogen gas to the substrate 100, dichlorosilane gas may be supplied to the substrate 100. Dichlorosilane gas is easily adsorbed on the surface of silicon and the surface of silicon germanium, but is not easily adsorbed on the surface of the insulating film 120. Therefore, when dichlorosilane gas is supplied to the substrate 100, dichlorosilane gas is adsorbed on the surface of the crystal nuclei 130. In contrast, dichlorosilane gas is not or hardly adsorbed on the surface of the insulating film 120. As a result, the crystal nuclei 130 generated in step S2 can be grown without generating crystal nuclei 130 on the surface of the insulating film 120. The temperature of the substrate 100 when the crystal nuclei 130 are grown by using dichlorosilane gas is, for example, 600° C. or more and 900° C. or less. Alternatively, hydrogen chloride (HCl) gas may be added to dichlorosilane gas. In this case, crystal nuclei 130 are less likely to be further generated on the surface of the insulating film 120, and the crystal nuclei 130 generated in step S2 are more likely to grow. Alternatively, a mixed gas of monosilane gas and hydrogen chloride gas may be supplied to the substrate 100. In this case as well, the crystal nuclei 130 generated in step S2 can be grown without generating crystal nuclei 130 on the surface of the insulating film 120.

As described above, according to the film-forming method according to the embodiment, in step S1, the substrate 100 having the insulating film 120 at its surface is prepared. Next, in step S2, the crystal nuclei 130 containing silicon are generated on the insulating film 120. Next, in step S3, the generated crystal nuclei 130 are grown. In this case, the density of the crystal nuclei 130 can be controlled by changing the conditions for generating the crystal nuclei 130 in step S2, and the size of the crystal nuclei 130 can be controlled by changing the conditions for growing the crystal nuclei 130 in step S3. That is, the density and size of the crystal nuclei 130 can be controlled.

Between steps S2 and S3, an inert gas such as nitrogen gas or argon gas may be supplied to the substrate 100 to purge the space in which the substrate 100 is present. For example, when the temperature of the substrate 100 in step S2 is different from the temperature of the substrate 100 in step S3, purging can shorten the time required for changing the temperature.

### Film-Forming Apparatus

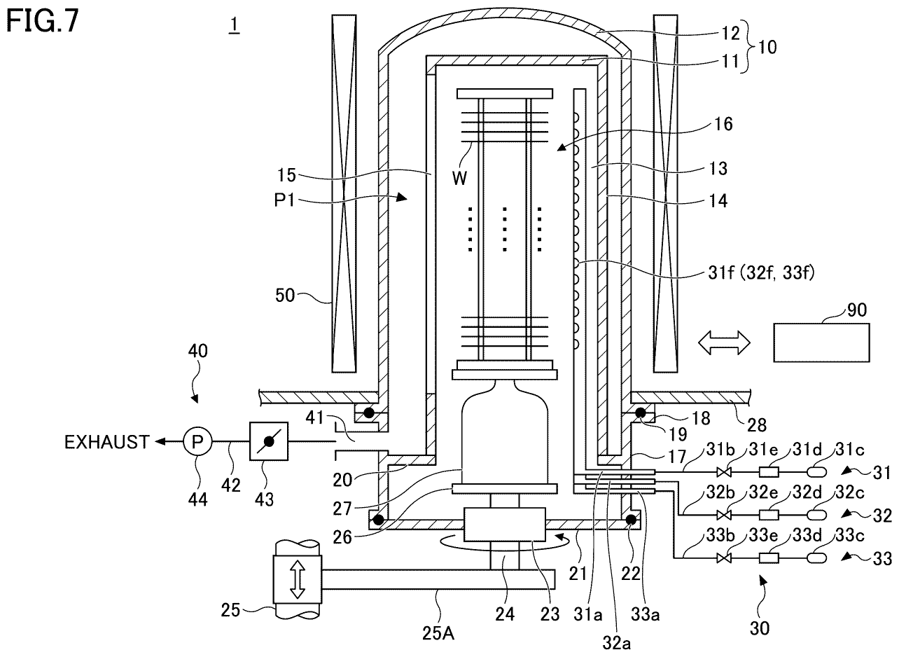

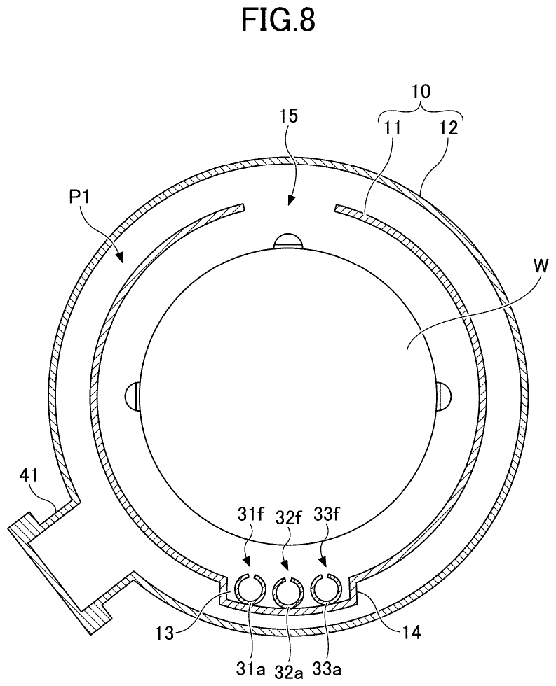

A film-forming apparatus 1 according to an embodiment will be described with reference to FIGS. 7 and 8. FIG. 7 is a vertical cross-sectional diagram illustrating the film-forming apparatus 1 according to an embodiment. FIG. 8 is a horizontal cross-sectional diagram illustrating the film-forming apparatus 1 according to an embodiment.

The film-forming apparatus 1 is a batch type apparatus which processes a plurality of (e.g., 50 to 150) substrates W at a time. The substrates W are, for example, semiconductor wafers. The film-forming apparatus 1 includes a process chamber 10, a gas supply 30, an exhaust 40, a heater 50, and a controller 90.

The inside of the process chamber 10 can be depressurized. The process chamber 10 is configured to house the substrates W. The process chamber 10 includes an inner tube 11 and an outer tube 12. The inner tube 11 has a cylindrical shape with a ceiling and an open lower end. The outer tube 12 has a cylindrical shape with a ceiling, which covers the outside of the inner tube 11, and an open lower end. The inner tube 11 and the outer tube 12 are formed of a heat-resistant material such as quartz. The inner tube 11 and the outer tube 12 have a double-tube structure arranged coaxially.

A housing 13 for housing gas supply tubes is formed along a longitudinal direction (vertical direction) on a side wall of the inner tube 11. For example, a part of the side wall of the inner tube 11 is projected outward to form a convex part 14, and the inside of the convex part 14 is formed as a housing 13.

A rectangular opening 15 is formed along a longitudinal direction on a side wall of the inner tube 11. The opening 15 faces the housing 13.

The opening 15 is a gas exhaust formed to exhaust gas in the inner tube 11. The length of the opening 15 is equal to the length of a boat 16 or longer than the length of the boat 16, so as to extend in the vertical direction.

The lower end of the process chamber 10 is supported by a cylindrical manifold 17. The manifold 17 is formed of, for example, stainless steel. A flange 18 is formed at the upper end of the manifold 17. The flange 18 supports the lower end of the outer tube 12. A seal member 19 such as an O-ring is provided between the flange 18 and the lower end of the outer tube 12. Thus, the inside of the outer tube 12 is maintained airtight.

An annular support 20 is provided on the upper inner wall of the manifold 17. The support 20 supports the lower end of the inner tube 11. A lid 21 is airtightly attached to the opening at the lower end of the manifold 17 via a seal member 22 such as an O-ring. Thus, the opening at the lower end of the process chamber 10, that is, the opening of the manifold 17 is airtightly closed. The lid 21 is formed of, for example, stainless steel.

A rotary shaft 24 is provided to penetrate the center of the lid 21 via a magnetic fluid seal 23. The lower part of the rotary shaft 24 is rotatably supported by an arm 25A of an elevating mechanism 25 composed of a boat elevator.

A rotary plate 26 is provided at the upper end of the rotary shaft 24. The boat 16 for holding the substrates W is placed on the rotary plate 26 via a quartz heat insulation table 27. The boat 16 is rotated by rotating the rotary shaft 24. The boat 16 is vertically moved integrally with the lid 21 by elevating and lowering the elevating mechanism 25. Thus, the boat 16 is inserted into and removed from the process chamber 10. The boat 16 can be accommodated in the process chamber 10. The boat 16 holds the plurality of substrates W in a shelf shape. The boat 16 holds the plurality of substrates W substantially horizontally at intervals in the vertical direction.

The gas supply 30 is configured to introduce various processing gases into the inner tube 11. The gas supply 30 includes a monosilane gas supply 31, a monogermane gas supply 32, and a hydrogen gas supply 33.

The monosilane gas supply 31 is provided with a gas supply tube 31a in the process chamber 10, and a supply passage 31b outside the process chamber 10. The supply passage 31b is provided with a monosilane gas source 31c, a mass flow controller 31d, and a valve 31e, in order from the upstream to the downstream in the gas flow direction. Thus, the monosilane gas supplied from the monosilane gas source 31c is controlled in timing by the valve 31e and adjusted to a predetermined flow rate by the mass flow controller 31d. The monosilane gas flows into the gas supply tube 31a from the supply passage 31b, and is discharged into the process chamber 10 from the gas supply tube 31a.

The monogermane gas supply 32 is provided with a gas supply tube 32a in the process chamber 10, and a supply passage 32b outside the process chamber 10. The supply passage 32b is provided with a monogermane gas source 32c, a mass flow controller 32d, and a valve 32e, in order from the upstream to the downstream in the gas flow direction. Thus, the monogermane gas supplied from the monogermane gas source 32c is controlled in timing by the valve 32e and adjusted to a predetermined flow rate by the mass flow controller 32d. The monogermane gas flows into the gas supply tube 32a from the supply passage 32b, and is discharged into the process chamber 10 from the gas supply tube 32a.

The hydrogen gas supply 33 is provided with a gas supply tube 33a in the process chamber 10, and a supply passage 33b outside the process chamber 10. The supply passage 33b is provided with a hydrogen gas source 33c, a mass flow controller 33d, and a valve 33e, in order from the upstream to the downstream in the gas flow direction. Thus, the hydrogen gas supplied from the hydrogen gas source 33c is controlled in timing by the valve 33e and adjusted to a predetermined flow rate by the mass flow controller 33d. The hydrogen gas flows into the gas supply tube 33a from the supply passage 33b, and is discharged into the process chamber 10 from the gas supply tube 33a.

The gas supply tubes 31a, 32a, and 33a are fixed to the manifold 17. The gas supply tubes 31a, 32a, and 33a are formed of, for example, quartz. The gas supply tubes 31a, 32a, and 33a extend linearly in the vertical direction in the vicinity of the inner tube 11, bend in an L-shape in the manifold 17, and extend in the horizontal direction, thereby penetrating the manifold 17. The gas supply tubes 31a, 32a, and 33a are provided side by side along the circumferential direction of the inner tube 11 and are formed at the same height.

A plurality of discharge ports 31f, 32f, and 33f are provided at respective locations of the gas supply tubes 31a, 32a, and 33a in the inner tubes 11. The discharge ports 31f, 32f, and 33f are formed at predetermined intervals along the extending direction of the gas supply tubes 31a, 32a, and 33a, respectively. The discharge ports 31f, 32f, and 33f discharge gas horizontally toward the substrates W from the outside in the radial direction of the substrate W. The discharge ports 31f, 32f, and 33f discharge gas in parallel with the principal surface of the substrate W. The interval between the discharge ports is set equal to, for example, the interval between the substrates W held by the boat 16. The position of the discharge ports in the height direction is set at, for example, an intermediate position between the substrates W adjacent in the vertical direction. In this case, the discharge ports can efficiently supply gases to the opposing surfaces of the adjacent substrates W.

The gas supply 30 may mix a plurality of types of gases (for example, monosilane gas, monogermane gas, and hydrogen gas) and discharge the mixed gas from a single gas supply tube. The gas supply tubes 31a, 32a, and 33a may have shapes and arrangements different from each other. The gas supply 30 may further include a gas supply tube for supplying another gas, for example, an inert gas.

The exhaust 40 exhausts gas that is discharged from the inner tube 11 via the opening 15 and then discharged from a gas outlet 41 via a space P1 between the inner tube 11 and the outer tube 12. The gas outlet 41 is formed in an upper side wall of the manifold 17 above the support 20. An exhaust flow path 42 is connected to the gas outlet 41. A pressure regulating valve 43 and a vacuum pump 44 are sequentially interposed in the exhaust flow path 42 to exhaust the inside of the process chamber 10.

The heater 50 is provided around the outer tube 12. The heater 50 is provided, for example, on a base plate 28. The heater 50 has a cylindrical shape so as to cover the outer tube 12. The heater 50 includes, for example, a heating element and heats each substrate W in the process chamber 10.

The controller 90 is an electronic circuit such as a central processing unit (CPU), a field programmable gate array (FPGA), or an application specific integrated circuit (ASIC). The controller 90 executes the various control operations described in the present specification by executing instruction codes stored in a memory or by being a circuit designed for a specific purpose.

### Operation of Film-Forming Apparatus

An operation of the film-forming apparatus 1, when a film-forming method according to an embodiment is carried out in the film-forming apparatus 1, will be described. The following operation of the film-forming apparatus 1 is carried out under the control of the controller 90.

First, the elevating mechanism 25 carries the boat 16 holding the plurality of substrates W into the process chamber 10, and the lid 21 airtightly closes the opening at the lower end of the process chamber 10 and seals it. Subsequently, the exhaust 40 depressurizes the inside of the process chamber 10, and the heater 50 adjusts the temperature of the substrates W to a predetermined temperature. Each substrate W may be the aforementioned substrate 100.

Next, the controller 90 controls the gas supply 30, the exhaust 40, and the heater 50 so that steps S2 and S3 of the film-forming method according to the embodiment are executed in this order.

Next, the controller 90 raises the pressure in the process chamber 10 to atmospheric pressure, lowers the temperature in the process chamber 10 to the carry-out temperature, and then controls the elevating mechanism 25 to carry out the boat 16 from the process chamber 10.

### Experimental Results

In the experiment, first, the substrate W having an insulating film at the surface was housed in the process chamber 10 of the film-forming apparatus 1. Next, the pressure in the process chamber 10 was reduced to the processing pressure, and the temperature of the substrate W was adjusted to the processing temperature. Next, SiH₄ gas, GeH₄ gas, and H₂ gas were supplied into the process chamber 10 to generate crystal nuclei of silicon germanium on the insulating film. In the experiment, silicon germanium crystal nuclei were generated under several conditions in which processing pressure, processing temperature, and flow rate of monosilane gas were different.

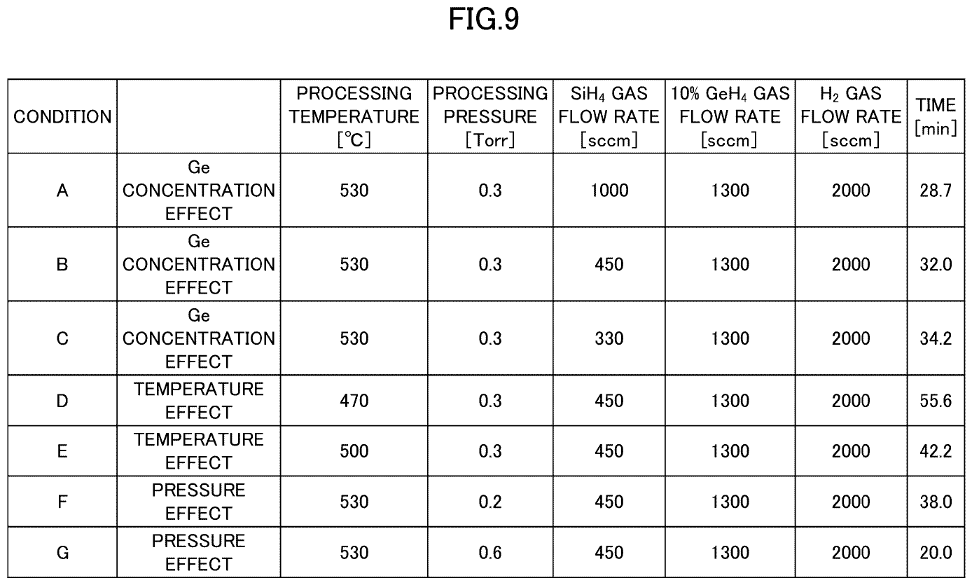

FIG. 9 is a table presenting the conditions for generating silicon germanium crystal nuclei. FIG. 9 represents the processing temperature [° C.], processing pressure [Torr], SiH₄ gas flow rate [sccm], 10% GeH₄ gas flow rate [sccm], H₂ gas flow rate [sccm], and time [minutes], under conditions A to G. The 10% GeH₄ gas means GeH₄ gas diluted to 10% with H₂ gas (GeH₄ gas/H₂ gas=10%/90%).

Conditions A, B, and C are conditions for confirming the effect of Ge concentration, and have different flow rates of SiH₄ gas from each other. The flow rate of SiH₄ gas under condition A is 1000 sccm. The flow rate of SiH₄ gas under condition B is 450 sccm. The flow rate of SiH₄ gas under condition C is 330 sccm.

Conditions D and E are conditions for confirming the effect of temperature, and have different processing temperatures from each other. The processing temperature under condition D is 470° C. The processing temperature under condition E is 500° C.

Conditions F and G are conditions for confirming the effect of pressure, and have different processing pressures from each other. The processing pressure under condition F is 0.2 Torr. The processing pressure under condition G is 0.6 Torr.

Next, the surface of the generated crystal nuclei was observed by scanning electron microscope (SEM).

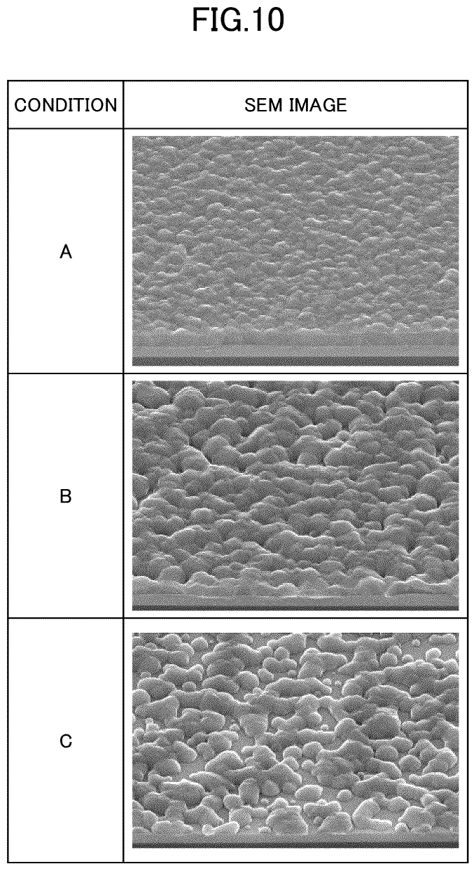

FIG. 10 is a diagram illustrating the results of observing the crystal nuclei of silicon germanium. FIG. 10 is SEM images of the surfaces of the crystal nuclei of silicon germanium generated under conditions A, B, and C. As illustrated in FIG. 10, it is recognized that the density of the crystal nuclei of silicon germanium is lower under condition B than under condition A, and that the density of the crystal nuclei of silicon germanium is lower under condition C than under condition B. These results indicated that the density of the crystal nuclei of silicon germanium can be reduced by reducing the flow rate of SiH₄ gas while the 10% GeH₄ gas flow rate is fixed. In other words, it was demonstrated that the density of the crystal nuclei of silicon germanium can be reduced by increasing the flow rate ratio of 10% GeH₄ gas to SiH₄ gas (10% GeH₄ gas/SiH₄ gas).

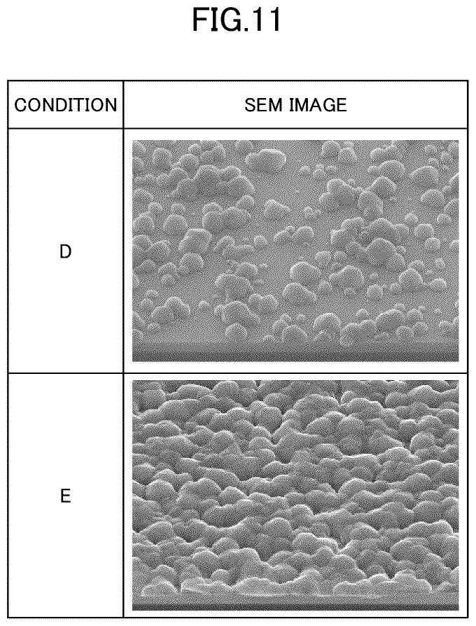

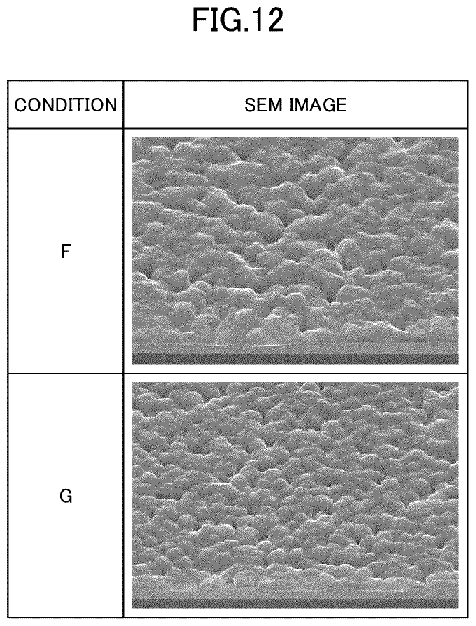

FIG. 11 is a diagram illustrating the results of observing the crystal nuclei of silicon germanium. FIG. 11 is SEM images of the surfaces of the crystal nuclei of silicon germanium generated under conditions D and E. As illustrated in FIG. 11, it is recognized that the density of the crystal nuclei of silicon germanium is lower under condition D than under condition E. This result indicated that the density of the crystal nuclei of silicon germanium can be reduced by lowering the processing temperature.

FIG. 12 is a diagram illustrating the results of observing the crystal nuclei of silicon germanium. FIG. 12 is SEM images of the surfaces of the crystal nuclei of silicon germanium generated under conditions F and G. As illustrated in FIG. 12, it is recognized that the density of the crystal nuclei of silicon germanium is lower under condition F than under condition G. This result indicated that the density of the crystal nuclei of silicon germanium can be reduced by lowering the processing pressure.

The embodiments disclosed herein should be considered illustrative and not limiting in all respects. The foregoing embodiments may be omitted, substituted, or modified in various ways without departing from the scope of the appended claims.

In the above embodiment, the case where the silicon-containing gas is monosilane (SiH₄) gas is described, but the present disclosure is not limited thereto. The silicon-containing gas may be SiH₄ gas, Si₂H₆ gas, Si₃H₈ gas, or a combination thereof.

In the above embodiment, the case where the germanium-containing gas is monogermane (GeH₄) gas is described, but the present disclosure is not limited thereto. The germanium-containing gas may be GeH₄ gas, Ge₂H₆ gas, Ge₃H₈ gas, or a combination thereof.

In the above embodiment, the case where the film-forming apparatus is a batch type apparatus for processing a plurality of substrates at a time is described, but the present disclosure is not limited thereto. For example, the film-forming apparatus may be a single-wafer type apparatus for processing substrates one by one. For example, the film-forming apparatus may be a semi-batch type apparatus for processing substrates by rotating a rotary table on which a plurality of substrates are mounted, revolving each substrate, and repeatedly passing each substrate through a processing gas supply region arranged along the radial direction of the rotary table.

According to the present disclosure, the density and size of the crystal nuclei can be controlled.

What is claimed is

1. A film-forming method, comprising:
preparing a substrate in which an insulating film is formed at a surface of the substrate;
generating crystal nuclei containing silicon on the insulating film; and
growing the generated crystal nuclei.

2. The film-forming method according to claim 1, wherein
the growing of the generated crystal nuclei includes supplying a silicon-containing gas and a germanium-containing gas to the substrate.

3. The film-forming method according to claim 1, wherein
the generating of the crystal nuclei includes supplying a silicon-containing gas and a germanium-containing gas to the substrate,
the growing of the generated crystal nuclei includes supplying the silicon-containing gas and the germanium-containing gas to the substrate, and
a second flow rate ratio of the germanium-containing gas to the silicon-containing gas in the growing of the crystal nuclei is higher than a first flow rate ratio of the germanium-containing gas to the silicon-containing gas in the generating of the crystal nuclei.

4. The film-forming method according to claim 3, wherein
in the generating of the crystal nuclei, a density of the crystal nuclei is controlled by changing at least one of the first flow rate ratio, a temperature of the substrate, or a pressure of a space in which the substrate is present.

5. The film-forming method according to claim 1, wherein
the generating of the crystal nuclei includes supplying a silicon-containing gas and a germanium-containing gas to the substrate,
the growing of the generated crystal nuclei includes supplying the silicon-containing gas and the germanium-containing gas to the substrate, and
a germanium atom concentration of the crystal nuclei grown by the growing of the crystal nuclei is higher than a germanium atom concentration of the crystal nuclei generated in the generating of the crystal nuclei.

6. The film-forming method according to claim 2, wherein
the silicon-containing gas is monosilane gas, and
the germanium-containing gas is monogermane gas.

7. The film-forming method according to claim 3, wherein
the silicon-containing gas is monosilane gas, and
the germanium-containing gas is monogermane gas.

8. The film-forming method according to claim 4, wherein
the silicon-containing gas is monosilane gas, and
the germanium-containing gas is monogermane gas.

9. The film-forming method according to claim 5, wherein
the silicon-containing gas is monosilane gas, and
the germanium-containing gas is monogermane gas.

10. The film-forming method according to claim 1, further comprising:
supplying an inert gas to the substrate, between the generating of the crystal nuclei and the growing of the generated crystal nuclei, to purge a space in which the substrate is present.

11. The film-forming method according to claim 2, further comprising:
supplying an inert gas to the substrate to purge a space in which the substrate is present, between the generating of the crystal nuclei and the growing of the crystal nuclei.

12. The film-forming method according to claim 3, further comprising:
supplying an inert gas to the substrate to purge a space in which the substrate is present, between the generating of the crystal nuclei and the growing of the crystal nuclei.

13. The film-forming method according to claim 4, further comprising:
supplying an inert gas to the substrate to purge a space in which the substrate is present, between the generating of the crystal nuclei and the growing of the crystal nuclei.

14. The film-forming method according to claim 5, further comprising:
supplying an inert gas to the substrate to purge a space in which the substrate is present, between the generating of the crystal nuclei and the growing of the crystal nuclei.

15. A film-forming apparatus, comprising:
a processor; and
a controller, wherein
the controller is configured to control the processor to execute:
preparing a substrate in which an insulating film is formed at a surface of the substrate;
generating crystal nuclei containing silicon on the insulating film; and
growing the generated crystal nuclei.
